(19) United States
(12) Patent Application Publication
(10) Pub. No.: US 2026/0076193 A1
(43) Pub. Date: Mar. 12, 2026

(54) POWER MODULE STRUCTURE, METHOD OF MANUFACTURING THE SAME, AND COOLER

(71) Applicant: HYUNDAI MOBIS CO., LTD., Seoul (KR)

(72) Inventor: Yu Cheol PARK, Yongin-si (KR)

(73) Assignee: HYUNDAI MOBIS CO., LTD., Seoul (KR)

(21) Appl. No.: 19/195,878

(22) Filed: May 1, 2025

(30) Foreign Application Priority Data
Sep. 10, 2024 (KR) 10-2024-0123205

(51) Int. Cl. H01L 23/373; H01L 21/48; H01L 23/367

(52) U.S. Cl. CPC H10W 40/255; H10W 40/22; H10W 70/02

(57) ABSTRACT

A power module, and a method of manufacturing the power module are provided. The power module includes a first heat sink, a substrate placed on an upper portion of the first heat sink, a semiconductor chip placed on an upper portion of the substrate, a clip placed on an upper portion of the semiconductor chip, and a second heat sink placed on an upper portion of the clip. At least one of the first heat sink and the second heat sink is formed with one or more protrusions.

### CROSS-REFERENCE TO RELATED APPLICATION

This application claims priority from and the benefit under 35 USC § 119(a) of Korean Patent Application No. 10-2024-0123205, filed on Sep. 10, 2024, in the Korean Intellectual Property Office, the entire disclosure of which is hereby incorporated by reference for all purposes as if set forth herein.

### BACKGROUND

### 1. Field

The present disclosure relates to a power module structure (e.g., a power module), a method of manufacturing the power module structure, and a cooler. More particularly, the present disclosure relates to a power module structure that is characterized by excellent heat dissipation performance, a simplified manufacturing process, reduced manufacturing costs that results in superior economic efficiency, and a compact volume that leads to high efficiency, a method of manufacturing the power module structure, and a cooler.

### 2. Description of the Related Art

Generally, power module structures include a semiconductor chip for power conversion and control, a structure for supporting the semiconductor chip, and a heat sink for dissipating and controlling heat generated from the semiconductor chip. The heat sink is primarily made of a material, such as aluminum or copper, having relatively high thermal conductivity, and is designed to have an increased surface area to maximize heat dissipation.

Particularly, single-sided cooling in conventional power modules refers to a scheme in which a heat sink is attached to a lower portion of a substrate to dissipate heat, thus providing a simple structure and ease of fabrication. However, there are limitations in handling high heat density, and an issue arises in that heat generated from a semiconductor chip, which is a heat source, is dissipated only in a downward direction.

On the other hand, double-sided cooling in conventional power modules refers to a scheme in which heat generated from a semiconductor chip is dissipated in both upward and downward directions, thus providing relatively high heat dissipation performance compared to the single-sided cooling, and ensuring reliable operation in high-power electronic devices. However, there are issues of a complicated manufacturing process and high production costs. Furthermore, in an upper portion of the substrate, heat from the semiconductor chip is transferred through a spacer, resulting in lower heat dissipation compared to the lower portion of the substrate, causing an issue of uneven temperature distribution. To overcome the aforementioned issues, there is a need to develop a power module structure with excellent heat dissipation performance, which can be manufactured through a simplified process, at lower production costs, and with a reduced volume.

The related art includes Korean Patent Publication No. 10-2009-0051640.

### SUMMARY

Various embodiments are directed to providing a power module structure with excellent heat dissipation performance, a method of manufacturing the power module structure, and a cooler.

Various embodiments are directed to providing a power module structure that can be manufactured through a simplified process with reduced manufacturing costs, thereby achieving superior economic efficiency, a method of manufacturing the power module structure, and a cooler.

Various embodiments are directed to providing a power module structure with a reduced volume, thus achieving improved efficiency, a method of manufacturing the power module structure, and a cooler.

The above and other objectives of the present disclosure may be fully achieved as set forth below.

In a general aspect of the disclosure, a power module including a first heat sink, a substrate placed on an upper portion of the first heat sink, a semiconductor chip placed on an upper portion of the substrate, a clip placed on an upper portion of the semiconductor chip, and a second heat sink placed on an upper portion of the clip, wherein at least one of the first heat sink and the second heat sink is formed with one or more protrusions.

The semiconductor chip and the clip may be bonded together.

The semiconductor chip and the clip may be soldered together.

The substrate may include a direct bonded copper (DBC) substrate.

The power module may further include a terminal that is formed in one side of the substrate.

The power module may further include a negative temperature coefficient (NTC) thermistor that is formed in one side of the substrate.

The power module may further include a thermal interface material (TIM) that is formed between the substrate and the first heat sink.

In another general aspect of the disclosure, a power module includes a heat sink-integrated substrate, a semiconductor chip placed on an upper portion of the heat sink-integrated substrate, and a heat sink-integrated clip placed on an upper portion of the semiconductor chip, wherein the heat sink-integrated substrate and the heat sink-integrated clip are each formed with a plurality of protrusions.

The heat sink-integrated clip may include a clip configured to transmit current in a power module, wherein the clip is made of a material that dissipates heat, wherein one end of the clip has a stepped structure and configured to electrically connect to the substrate, wherein the clip includes a first surface in contact with an upper portion of the semiconductor chip, and a second surface facing away from the first surface, and wherein the second surface includes one or more protrusions.

The heat sink-integrated substrate may include a ceramic insulating layer, an upper conductive layer placed on an upper portion of the ceramic insulating layer, and a heat sink placed on a lower portion of the ceramic insulating layer, wherein the heat sink includes a first surface in contact with the ceramic insulating layer, and a second surface facing away from the first surface, and wherein the second surface includes one or more protrusions.

The semiconductor chip and the heat sink-integrated clip may be bonded together.

The semiconductor chip and the heat sink-integrated clip may be soldered together.

The power module may further include a terminal that is formed in one side of the heat sink-integrated substrate.

The power module may further include a negative temperature coefficient (NTC) thermistor that is formed in one side of the heat sink-integrated substrate.

In yet another general aspect of the disclosure, a method of manufacturing a power module includes placing a semiconductor chip on an upper portion of a heat sink-integrated substrate, placing a heat sink-integrated clip on an upper portion of the semiconductor chip, and bonding one side of the heat sink-integrated clip to a lead to establish electrical connection therebetween, wherein the heat sink-integrated substrate and the heat sink-integrated clip each include one or more protrusions.

Heat may be dissipated from opposite sides of the semiconductor chip to directly cool the semiconductor chip.

### BRIEF DESCRIPTION OF THE DRAWINGS

FIG. 1 is a schematic sectional view illustrating a heat sink-integrated clip according to an embodiment of the present disclosure.

FIG. 2 is a schematic sectional view illustrating a heat sink-integrated clip according to another embodiment of the present disclosure.

FIG. 3 is a manufacturing process diagram illustrating a method of manufacturing a heat sink-integrated clip according to an embodiment of the present disclosure.

FIG. 4 is a manufacturing process diagram illustrating a method of manufacturing a heat sink-integrated clip according to another embodiment of the present disclosure.

FIG. 5 is a schematic sectional view illustrating a heat sink-integrated substrate according to an embodiment of the present disclosure.

FIG. 6 is a manufacturing process diagram illustrating a method of manufacturing a heat sink-integrated substrate according to an embodiment of the present disclosure.

FIG. 7 is a manufacturing process diagram illustrating a method of manufacturing a heat sink-integrated substrate according to another embodiment of the present disclosure.

FIG. 8 is a side sectional view illustrating a power module structure provided with a clip having a heat sink placed on an upper portion thereof according to an embodiment of the present disclosure.

FIG. 9 is a side sectional view illustrating a power module structure provided with a heat sink-integrated clip and a heat sink-integrated substrate according to an embodiment of the present disclosure.

FIG. 10 is a process flowchart pertaining to a method of manufacturing a power module structure provided with a clip having a heat sink placed on an upper portion thereof according to an embodiment of the present disclosure.

FIG. 11 is a process flowchart pertaining to a method of manufacturing a power module structure provided with a heat sink-integrated clip and a heat sink-integrated substrate according to an embodiment of the present disclosure.

FIG. 12 is a side sectional view illustrating a cooler including a power module structure provided with a clip having a heat sink placed on an upper portion thereof according to an embodiment of the present disclosure.

FIG. 13 is a side sectional view illustrating a cooler including a power module structure provided with a heat sink-integrated clip and a heat sink-integrated substrate according to an embodiment of the present disclosure.

FIG. 14 is a plan view of a cooler provided with a power module structure according to an embodiment of the present disclosure.

### DETAILED DESCRIPTION

Hereinafter, the present disclosure will be described in more detail with reference to the accompanying drawings. The accompanying drawings are provided only to aid in understanding of the preset disclosure, and the present disclosure is not limited by the accompanying drawings. The shapes, sizes, ratios, angles, numbers, and the like illustrated in the accompanying drawings are merely for illustrative purposes, and the present disclosure is not limited to those shown in the drawings.

Like reference numerals generally denote like elements throughout the specification. Furthermore, in the following description, a detailed explanation of known related technologies may be omitted to avoid unnecessarily obscuring the subject matter of the present disclosure.

The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more other parts may be positioned between the two parts unless the terms are used with the term “immediately” or “directly”.

Spatially relative terms, such as “upper portion”, “upper surface”, “lower portion”, “lower surface”, and the like, are defined with reference to the drawings, and do not indicate absolute orientations. In other words, “upper portion (surface)” may be defined as “lower portion (surface)” and vice versa depending on the point of view.

Hereinafter, a power module structure, a method of manufacturing the power module structure, and a cooler according to the present disclosure will be described in detail with reference to the accompanying drawings.

One aspect of the present disclosure relates to a heat sink-integrated clip.

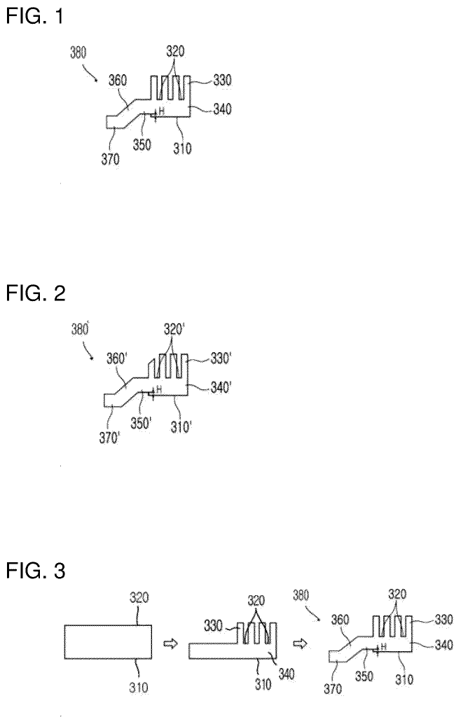

FIG. 1 is a schematic sectional view illustrating a heat sink-integrated clip according to an embodiment of the present disclosure, and FIG. 2 is a schematic sectional view illustrating a heat sink-integrated clip according to another embodiment of the present disclosure.

Referring to FIGS. 1 and 2, the heat sink-integrated clip 380 or 380′ may be placed on an upper portion of a semiconductor chip and electrically connect the semiconductor chip to a lead. Furthermore, the clip 380 or 380′ may minimize contact resistance to reduce electrical loss and provide mechanical stability.

The clip 380 or 380′ may be provided with a connection portion 350 or 350′ extending from a semiconductor chip contact portion 340 or 340′, may be embodied with a downset portion 360 or 360′ formed in a bent shape to connect with the lead, and may include a lead contact portion 370 or 370′ that comes into contact with the lead. Heat transmitted to the clip 380 or 380′ may be transferred to a substrate through the extended connection portion 350 or 350′. The clip 380 or 380′ may include a spring clip, a pin clip, a bar clip, or the like, but is not limited thereto.

One end of the clip 380 or 380′ may have a stepped structure H to electrically connect with the substrate. The stepped structure H allows one side of the clip 380 or 380′ to come into contact with a specific point of the substrate, thereby enhancing the electrical connection therebetween. In the case where the stepped structure H is present, an electrical contact area may be maximized, and contact resistance may be minimized, thus enabling reliable electrical connection, and allowing efficient transmission of electrical signals and power.

The clip 380 or 380′ may include a first surface 310 or 310′ that is in contact with the upper portion of the semiconductor chip, and a second surface 320 or 320′ that faces away from the first surface 310 or 310′, with a plurality of protrusions 330 or 330′ formed on the second surface 320 or 320′.

The first surface 310 or 310′ may have a plate shape with a relatively large heat dissipation area to enhance heat transfer.

The plurality of protrusions 330 or 330′ of the second surface 320 or 320′ may come into direct contact with cooling fluid that continuously circulates along a flow path to perform heat exchange. In other words, heat generated from the semiconductor chip may be transmitted to the plurality of protrusions 330 or 330′ and dissipated by the external cooling fluid, so that the semiconductor chip can be maintained at a constant temperature. Furthermore, due to the plurality of protrusions 330 or 330′, the contact area with the cooling fluid may increase, thus ensuring excellent heat dissipation performance.

The plurality of protrusions 330 or 330′ may each have a pin shape, such as a cylinder or a polygonal prism, and preferably may have a shape of a rectangular prism, but are not limited thereto. The plurality of protrusions 330 or 330′ may be horizontally arranged with intervals therebetween, thus enhancing a flow rate of the cooling fluid and cooling efficiency in the aforementioned structure, thereby providing excellent heat dissipation performance. The height of the plurality of protrusions 330 or 330′ is not limited so long as it does not exceed a perimeter of epoxy molding. The intervals and diameter of the plurality of protrusions 330 or 330′ are not limited so long as they do not exceed the size of the clip.

A volumetric ratio occupied by the plurality of protrusions 330 or 330′ on the second surface 320 or 320′ is not limited within a range in which cracks can be prevented from occurring in the semiconductor chip and a solder layer, taking into account the height, intervals, and diameter of the plurality of protrusions 330 or 330′.

The clip 380 or 380′ is configured to dissipate heat transmitted to the upper portions of semiconductor chips and may be made of a heat-dissipating material, such as aluminum, copper, steel, or ceramic, and preferably may be made of copper. However, the material of the clip 380 or 380′ is not limited to the aforementioned materials. Particularly, copper may provide superior heat dissipation performance for the power module structure due to high thermal conductivity thereof, and can reduce manufacturing costs due to low price thereof.

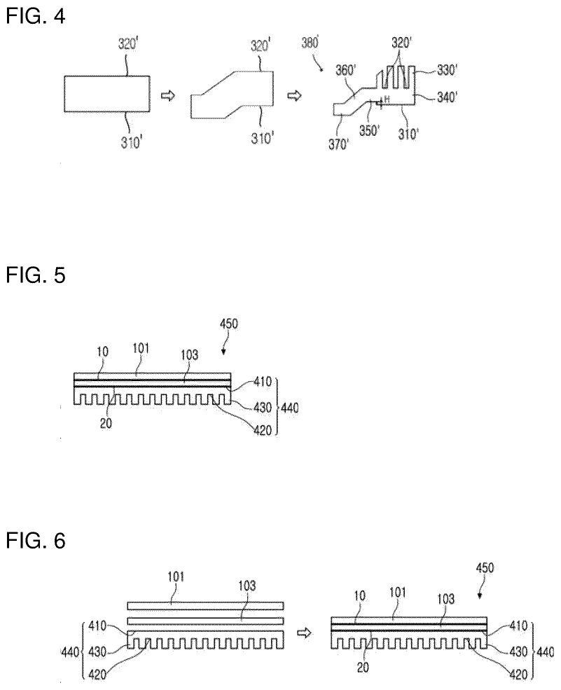

FIG. 3 is a manufacturing process diagram illustrating a method of manufacturing a heat sink-integrated clip according to an embodiment of the present disclosure, and FIG. 4 is a manufacturing process diagram illustrating a method of manufacturing a heat sink-integrated clip according to another embodiment of the present disclosure.

Referring to FIG. 3, the manufacturing method may include the step of loading a clip; the step of processing one side of the clip into various pin shapes; and the step of bending the clip. The clip, which is a plate-shaped metal conductor, may include a portion to be formed as the semiconductor chip contact portion 340, a portion to be formed as the downset portion 360, a portion to be formed as the connection portion 350, and a portion to be formed as the lead contact portion 370. To manufacture the heat sink-integrated clip 380, the clip that is a plate-shaped metal conductor is first loaded. Subsequently, the semiconductor chip contact portion 340 may be processed into various pin shapes to include the plurality of protrusions 330 that are horizontally arranged with intervals therebetween on the second surface 320, which faces away from the first surface 310 in contact with the upper portion of the semiconductor chip. Thereafter, a portion of the clip may be bent so that the downset portion 360 and the connection portion 350 form a specific angle. The lead contact portion 370 may be formed by bending a distal end of the clip to be parallel to the lead to facilitate contact with the lead, thereby increasing the contact area with the lead.

Referring to FIG. 4, the manufacturing method may include the step of loading a clip; the step of bending one side of the clip; and the step of processing the one side of the clip into various pin shapes. To manufacture the heat sink-integrated clip 380′, the clip that is a plate-shaped metal conductor is first loaded. Thereafter, a portion of the clip may be bent so that the downset portion 360′ and the connection portion 350′ form a specific angle. The lead contact portion 370′ may be formed by bending a distal end of the clip in a parallel shape. Subsequently, to form the plurality of protrusions 330′ that are horizontally arranged with intervals therebetween on the second surface 320′, which faces away from the first surface 310′ in contact with the upper portion of the semiconductor chip, and on an upper portion of the downset portion 360′, a forging process involving heating, shaping, and cooling may be performed.

Another aspect of the present disclosure relates to a heat sink-integrated substrate.

FIG. 5 is a schematic sectional view illustrating a heat sink-integrated substrate according to an embodiment of the present disclosure.

Referring to FIG. 5, the heat sink-integrated substrate 450 may include a ceramic insulating layer 103, an upper conductive layer 101 placed on an upper portion of the ceramic insulating layer 103, and a heat sink 440 placed on a lower portion of the ceramic insulating layer 103.

The upper conductive layer 101 may be placed on an upper surface of the ceramic insulating layer 103 to enhance efficiency of dissipating heat generated from the semiconductor chip, thus conducting electric current and dispersing heat. The thickness of the upper conductive layer 101 may range from 0.2 mm to 0.8 mm. In specific embodiments, the thickness may range from 0.25 mm to 0.7 mm, for instance, from 0.3 mm to 0.65 mm. Within the ranges, sufficient insulation can be secured, thus resulting in excellent heat dissipation performance. The upper conductive layer 101 may include a metal having relatively high conductivity, such as copper or a copper alloy, aluminum or an aluminum alloy, but is not limited thereto.

The ceramic insulating layer 103 may prevent electrical contact between the upper conductive layer 101 and the heat sink 440, thereby ensuring safety, and may effectively dissipate heat due to the relatively high thermal conductivity thereof. The thickness of the ceramic insulating layer 103 is not limited so long as it can pass voltage resistance tests, satisfy thermal resistance requirements, and prevent cracks from occurring. Under the aforementioned conditions, sufficient insulation can be secured, thus resulting in excellent heat dissipation performance. The ceramic insulating layer 103 may include insulating materials, such as Al₂O₃, SiO₂, BeO, or AlN, but is not limited thereto.

The heat sink 440 may be placed on a lower surface of the ceramic insulating layer 103 to diffuse heat in a planar direction, thereby preventing degradation of the semiconductor chip. The heat sink 440 may include a first surface 410 that is in contact with the ceramic insulating layer 103, and a second surface 420 that faces away from the first surface 410. The second surface 420 may be formed with a plurality of protrusions 430.

An upper surface of the first surface 410, which is in direct contact with an electrode pattern, may have a plate shape with a relatively large heat dissipation area to enhance heat transfer.

The plurality of protrusions 430 of the second surface 420 may come into direct contact with cooling fluid that circulates along a flow path to perform heat exchange. In other words, heat generated from the semiconductor chip may be transmitted to the plurality of protrusions 430 and dissipated by the external cooling fluid, so that the semiconductor chip can be maintained at a constant temperature. Furthermore, due to the plurality of protrusions 430, the contact area with the cooling fluid may increase, thus ensuring excellent heat dissipation performance.

The plurality of protrusions 430 may each have a pin shape, such as a cylinder or a polygonal prism, and preferably may have a shape of a rectangular prism, but are not limited thereto. The plurality of protrusions 430 may be horizontally arranged with intervals therebetween, thus enhancing a flow rate of the cooling fluid and cooling efficiency in the aforementioned structure, thereby providing excellent heat dissipation performance. The height of the plurality of protrusions 430 is not limited so long as it does not exceed a perimeter of epoxy molding. The intervals and diameter of the plurality of protrusions 430 are not limited so long as they do not exceed the size of the heat sink 440.

A volumetric ratio occupied by the plurality of protrusions 430 on the second surface 420 is not limited so long as cracks can be prevented from occurring in the semiconductor chip and a solder layer, taking into account the height, intervals, and diameter of the plurality of protrusions 430.

The heat sink 440 may include metals capable of transferring and dissipating heat, such as Cu or a Cu alloy, and Al or an Al alloy, as well as materials such as AlN, Si₃N₄, ZTA, Al₂O₃, and SiC, but is not limited thereto.

The ceramic insulating layer 103 and the upper conductive layer 101 may be bonded using a brazing layer 10, and the ceramic insulating layer 103 and the heat sink 440 may be bonded using a brazing layer 20.

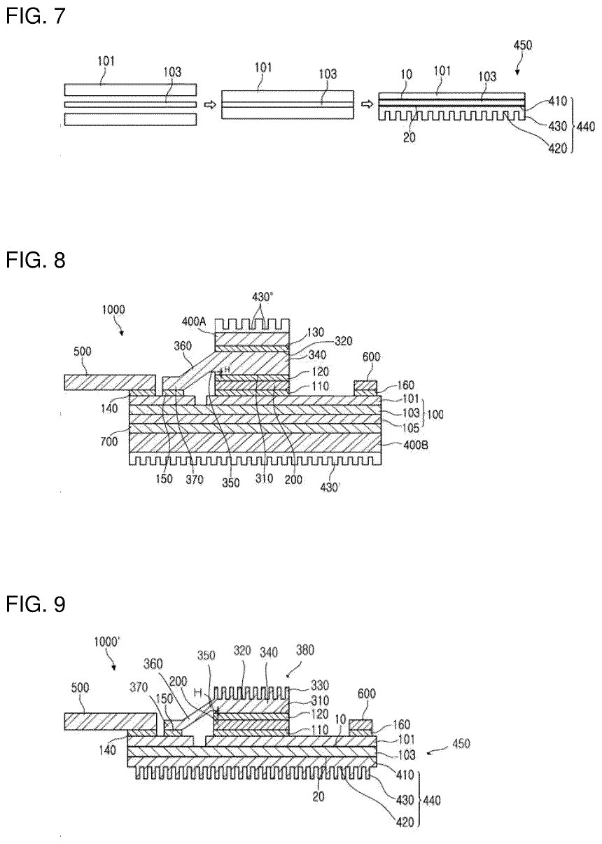

FIG. 6 is a manufacturing process diagram illustrating a method of manufacturing a heat sink-integrated substrate according to an embodiment of the present disclosure, and FIG. 7 is a manufacturing process diagram illustrating a method of manufacturing a heat sink-integrated substrate according to another embodiment of the present disclosure.

Referring to FIG. 6, the manufacturing method includes the step of loading a processed material of the substrate, and the step of brazing the material. First, may be loaded to manufacture the heat sink-integrated substrate 450 the ceramic insulating layer 103, which serves as the material of the substrate, a metal plate processed to a certain thickness to form the upper conductive layer 101, and the heat sink 440 processed into various pin shapes to include the plurality of protrusions 430 horizontally arranged with intervals therebetween on the second surface 420, which faces away from the first surface 410 that is in contact with the lower portion of the ceramic insulating layer 103. Thereafter, the ceramic insulating layer 103 and the upper conductive layer 101 may be bonded using the brazing layer 10, and the ceramic insulating layer 103 and the heat sink 440 may be bonded using the brazing layer 20, the brazing layers 10 and 20 being made of materials such as Ag, AgCu, and AgCuTi. The material of the brazing layers 10 and 20 may have relatively high thermal conductivity, thus improving bonding strength, and enhancing heat dissipation efficiency. In addition, the thickness of the brazing layers 10 and 20 and the brazing temperature are not limited, so long as reliability and thermal resistance requirements can be satisfied. The brazing process may ensure excellent bonding reliability, simplify the manufacturing process compared to conventional arts, and reduce manufacturing costs, thereby resulting in superior economic efficiency.

Referring to FIG. 7, the manufacturing method includes the step of loading a material of the substrate, the step of brazing the material, and the step of processing the material of the substrate. To manufacture the heat sink-integrated substrate 450, the ceramic insulating layer 103, which serves as the material of the substrate, a metal plate to be formed into the upper conductive layer 101, and a metal plate to be formed into the heat sink 440 may be loaded. Thereafter, the ceramic insulating layer 103 and the upper conductive layer 101 may be bonded using the brazing layer 10, and the ceramic insulating layer 103 and the heat sink 440 may be bonded using the brazing layer 20, the brazing layers 10 and 20 being made of materials such as Ag, AgCu, and AgCuTi. Subsequently, the heat sink 440 may be processed into various pin shapes to include the plurality of protrusions 430 that are horizontally arranged with intervals therebetween on the second surface 420, which faces away from the first surface 410 that is in contact with a lower portion of the ceramic insulating layer 103. Furthermore, the metal plate that is placed on the upper portion of the ceramic insulating layer 103 may be processed to have a constant thickness.

Another aspect of the present disclosure relates to a power module structure.

FIG. 8 is a side sectional view illustrating a power module structure including a clip with a heat sink placed on an upper portion thereof according to an embodiment of the present disclosure.

Referring to FIG. 8, a power module structure 1000 according to the present disclosure may include: a first heat sink 400B; a substrate 100 placed on an upper portion of the first heat sink 400B; a semiconductor chip 200 placed on an upper portion of the substrate 100; a clip 300 placed on an upper portion of the semiconductor chip 200; and a second heat sink 400A placed on the upper portion of the clip 300. At least one of the first heat sink 400B and the second heat sink 400A is formed with a plurality of protrusions 430′ or 430″.

The first heat sink 400B may function to efficiently dissipate heat generated from the semiconductor chip 200 to ensure the stability of the power module, and may include pins or ribs that increase a surface area of the first heat sink 400B to maximize heat dissipation, and a plate that receives heat and makes contact with the substrate 100. In the case where the plate is used, the plate can provide a relatively large surface area to uniformly disperse heat, and may offer excellent mechanical strength and durability. The first heat sink 400B may include metals capable of transferring and dissipating heat, such as Cu or a Cu alloy, and Al or an Al alloy, as well as materials such as AlN, Si₃N₄, ZTA, Al₂O₃, and SiC, but is not limited thereto.

The substrate 100 may be placed on the upper portion of the first heat sink 400B. The substrate 100 may include a printed circuit board (PCB), a flexible printed circuit board (FPCB), a direct bonded copper (DBC) substrate, or a bare copper (Bare Cu) substrate, and preferably may be a DBC substrate. However, the substrate 100 is not limited to the aforementioned examples.

The DBC substrate may include a ceramic insulating layer 103, an upper conductive layer 101 placed on an upper portion of the ceramic insulating layer 103, and a lower conductive layer 105 placed on a lower portion of the ceramic insulating layer 103. The ceramic insulating layer 103 may include insulating materials, such as Al₂O₃, SiO₂, BeO, or AlN, but is not limited thereto.

The upper conductive layer 101 and the lower conductive layer 105 may each include a Cu layer. The DBC substrate may enhance metal bonding with bonding portions 110, 120, 130, 140, 150, and 160, such as solder layers.

The semiconductor chip 200 may be placed on the upper portion of the substrate 100. The semiconductor chip 200 may include a material such as Si, SiC, GaN, GaAs, InP, Ge, AlN, ZnO, or CdTe, but is not limited thereto.

The clip 300 may be placed on the upper portion of the semiconductor chip 200. The clip 300 can transmit electric current in the power module. Furthermore, the clip 300 may minimize contact resistance to reduce electrical loss, reinforce electrical connection between the semiconductor chip 200 and the lead, and provide mechanical stability. The clip 300 may include a spring clip, a pin clip, a bar clip, or the like. The clip 300 may include a connection portion 350 extending from a contact portion of the semiconductor chip 200, and may be embodied with a downset portion 360 formed in a bent shape to connect with the lead. The clip 300 may include a spring clip, a pin clip, a bar clip, or the like.

The second heat sink 400A may function to efficiently dissipate heat generated from the semiconductor chip 200 to ensure the stability of the power module, and may include pins or ribs that increase a surface area of the second heat sink 400A to maximize heat dissipation, and a plate that receives heat and makes contact with the substrate 100. In the case where the plate is used, the plate can provide a relatively large surface area to uniformly disperse heat, and may offer excellent mechanical strength and durability. The second heat sink 400A may include metals capable of transferring and dissipating heat, such as Cu or a Cu alloy, and Al or an Al alloy, as well as materials such as AlN, Si₃N₄, ZTA, Al₂O₃, and SiC, but is not limited thereto.

The second heat sink 400A may be placed on the upper portion of the clip 300. In the case of double-sided cooling in the conventional power modules, two substrates are used, and a spacer for electrical connection is required. However, in the present disclosure, a structurally complex portion may be simplified by attaching the second heat sink 400A on top of the clip 300, thereby reducing manufacturing costs and improving economic efficiency. Furthermore, since the spacer and substrate used in the heat dissipation process are eliminated, the heat dissipation performance can be superior compared to the conventional double-sided cooling, and the overall volume of the power module can be reduced, thereby resulting in improved efficiency.

A terminal 500 may be formed on one side of the substrate 100. The terminal 500 may assist in heat dissipation by transferring heat to the substrate 100 or the first heat sink 400B, provide electrical connection between an internal electric circuit of the power module and an external circuit or system, and mechanically fix and support the power module. The terminal 500 may have a form, such as an external threaded type, plug type, clip type, or weld type, and may be made of a material, such as copper, aluminum, or brass. The terminal 500 formed on one side of the substrate 100 can improve the safety and reliability of the power module.

A negative temperature coefficient (NTC) thermistor 600 may be formed on one side of the substrate 100. The NTC thermistor 600, which serves as a temperature sensing element, may be placed on the upper portion of the substrate 100, and may measure the temperature of the semiconductor chip 200 in real time. The NTC thermistor 600 may have a relatively high resistance-temperature coefficient, thus allowing precise temperature measurement, and may have a simple structure, enabling miniaturization, and be suitable for mass production due to reliable price stability. Furthermore, the NTC thermistor 600 may be less affected by pressure, magnetic fields, and other factors, provide excellent mechanical strength and workability, and have a relatively high response speed.

A thermal interface material (TIM) may be formed between the substrate 100 and the first heat sink 400B. Particularly, the TIM 700 may include a solder layer. The TIM 700 may transfer heat generated from the substrate 100 to the first heat sink 400B, and improve structural stability.

The semiconductor chip 200 and the clip 300 may be bonded by soldering. Furthermore, the substrate 100 and the semiconductor chip 200, the clip 300 and the second heat sink 400A, the substrate 100 and the terminal 500, as well as the substrate 100 and the NTC thermistor 600 may also be bonded by soldering. The bonding portions 110, 120, 130, 140, 150, and 160, such as solder layers, may strengthen physical connections, thereby providing excellent mechanical stability and enabling effective heat transfer to achieve superior heat dissipation performance.

FIG. 9 is a side sectional view of a power module structure including a heat sink-integrated clip and a heat sink-integrated substrate according to an embodiment of the present disclosure.

Referring to FIG. 9, a power module structure 1000′ according to the present disclosure may include: a heat sink-integrated substrate 450, a semiconductor chip 200 placed on an upper portion of the heat sink-integrated substrate 450, and a heat sink-integrated clip 380 placed on an upper portion of the semiconductor chip 200.

The heat sink-integrated substrate 450, the semiconductor chip 200, and the heat sink-integrated clip 380 are as described above, and therefore, further explanation is omitted.

A terminal 500 may be formed on one side of the heat sink-integrated substrate 450. The terminal 500 is as described above, and therefore, further explanation is omitted.

An NTC thermistor 600 may be formed on one side of the heat sink-integrated substrate 450. The NTC thermistor 600 is as described above, and therefore, further explanation is omitted.

The semiconductor chip 200 and the heat sink-integrated clip 380 may be bonded by soldering. Furthermore, the heat sink-integrated substrate 450 and the semiconductor chip 200, the heat sink-integrated substrate 450 and the terminal 500, and the heat sink-integrated substrate 450 and the NTC thermistor 600 may also be bonded by soldering. The bonding portions 110, 120, 130, 140, 150, and 160, such as solder layers, may strengthen physical connections, thereby providing excellent mechanical stability and enabling effective heat transfer to achieve superior heat dissipation performance.

Another aspect of the present disclosure relates to a method of manufacturing a power module structure.

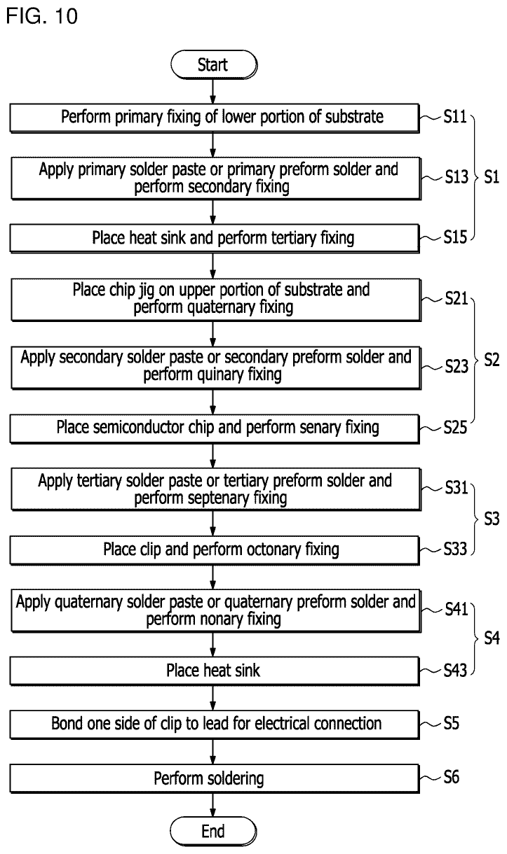

FIG. 10 is a process flowchart pertaining to a method of manufacturing a power module structure including a clip with a heat sink placed on an upper portion thereof according to an embodiment of the present disclosure.

Referring to FIG. 10, the method may include step S1 of placing a substrate on an upper portion of a first heat sink; step S2 of placing a semiconductor chip on an upper portion of the substrate; step S3 of placing a clip on an upper portion of the semiconductor chip; step S4 of placing a second heat sink on an upper portion of the clip; and step S5 of bonding one side of the clip to a lead to establish electrical connection therebetween. At least one of the first heat sink and the second heat sink may include a plurality of protrusions.

In step S1 of placing the substrate on the upper portion of the first heat sink, a lower portion of the substrate may be primarily fixed (in step S11). Thereafter, a primary solder paste or a primary preform solder may be applied to the lower portion of the substrate, and secondary fixing may be performed (in step S13). Subsequently, the heat sink may be placed, and tertiary fixing may be performed (in step S15).

In step S2 of placing the semiconductor chip on the upper portion of the substrate, a chip jig may be placed to locate the semiconductor chip at an accurate position, and quaternary fixing may be performed (in step S21). Thereafter, secondary solder paste or secondary preform solder may be applied, and quinary fixing may be performed (in step S23). Subsequently, the semiconductor chip may be placed, and senary fixing may be performed (in step S25).

Furthermore, a terminal may be placed and fixed at an appropriate position on the substrate to ensure electrical connection.

In step S3 of placing the clip on the upper portion of the semiconductor chip, tertiary solder paste or tertiary preform solder may be applied on the upper portion of the semiconductor chip, and septenary fixing may be performed (in step S31). Thereafter, the clip may be placed, and octonary fixing may be performed (in step S33).

In step S4 of placing the second heat sink on an upper portion of the clip, quaternary solder paste or quaternary preform solder may be applied on the upper portion of the clip, and nonary fixing may be performed (in step S41). Thereafter, the heat sink may be placed (in step S43).

Step S5 of bonding one side of the clip to the lead to establish electrical connection may be performed using soldering. In this step, soldering equipment may be used to heat the applied solder to a set temperature for a specified period of time, thus melting the solder and connecting the lead and the clip. Furthermore, the soldering equipment may be used to heat the applied solder to a set temperature for a specified period or time, thus melting the solder and connecting the first heat sink, the substrate, the semiconductor chip, the clip, and the second heat sink (in step S6). The set temperature for the soldering may range from 220° C. to 280° C., and the time required for heating may range from 5 minutes to 1 hour, but the conditions are not limited thereto. The temperature and time may be adjusted according to the material of the solder layers and the shape of the power module.

The power module structure may directly cool the semiconductor chip by dissipating heat from opposite sides of the semiconductor chip. In the conventional double-sided cooling, heat is dissipated through the spacer and the substrate, but the present disclosure enables effective heat dissipation from the semiconductor chip, thereby maximizing thermal performance. Particularly, in the case where the thermal performance of the power module is maximized in confined engine space, such as in electric vehicles, the output of the semiconductor chip may increase from 100 KW to 150 kW, thereby facilitating the production of high-output vehicles and enhancing usability. Furthermore, if the power module is manufactured with the same semiconductor chip output, the volume of the power module may be reduced, thus allowing for additional battery installation in remaining inverter space, thereby increasing the driving distance range.

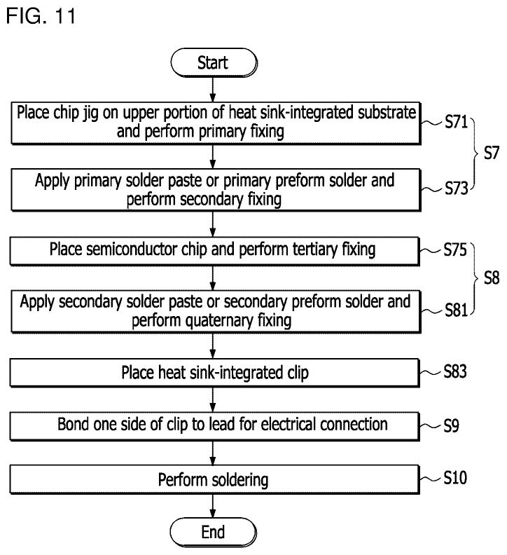

FIG. 11 is a process flowchart pertaining to a method of manufacturing a power module structure including a heat sink-integrated clip and a heat sink-integrated substrate according to an embodiment of the present disclosure.

Referring to FIG. 11, the method may include: step S7 of placing a semiconductor chip on an upper portion of the heat sink-integrated substrate; step S8 of placing the heat sink-integrated clip on the upper portion of the semiconductor chip; and step S9 of bonding one side of the heat sink-integrated clip to a lead to establish electrical connection therebetween. The heat sink-integrated substrate and the heat sink-integrated clip may each be formed with a plurality of protrusions.

In step S7 of placing the semiconductor chip on the upper portion of the heat sink-integrated substrate, a chip jig may be placed to locate the semiconductor chip at an accurate position, and primary fixing may be performed (in step S71). Thereafter, a primary solder paste or a primary preform solder may be applied, and secondary fixing may be performed (in step S73). Subsequently, the semiconductor chip may be placed, and tertiary fixing may be performed (in step 75).

Furthermore, a terminal may be placed and fixed at an appropriate position on the substrate to ensure electrical connection.

In step S8 of placing the heat sink-integrated clip on the upper portion of the semiconductor chip, secondary solder paste or secondary preform solder may be applied to the upper portion of the semiconductor chip, and quaternary fixing may be performed (in step S81). Thereafter, the heat sink-integrated clip may be placed, and quinary fixing may be performed (in step S83).

Step S9 of bonding one side of the heat sink-integrated clip to the lead to establish electrical connection may be performed using soldering. In this step, soldering equipment may be used to heat the applied solder to a set temperature for a specified period of time, thus melting the solder and connecting the lead and the heat sink-integrated clip. Furthermore, the soldering equipment may be used to heat the applied solder to a set temperature, thus melting the solder and connecting the heat sink-integrated substrate, the semiconductor chip, the heat sink-integrated clip (in step S10). The set temperature for the soldering may range from 220° C. to 280° C., and the time required for heating may range from 5 minutes to 1 hour, but the conditions are not limited thereto. The temperature and time may be adjusted according to the material of the solder layers and the shape of the power module.

The power module structure may directly cool the semiconductor chip by dissipating heat from opposite sides of the semiconductor chip. The direct cooling is as described above, and therefore, further explanation is omitted.

Another aspect of the present disclosure relates to a cooler. The cooler may be a cooler that uses the aforementioned power module structure, and may include O-rings on upper and lower portions of a part that comes into surface contact with a housing.

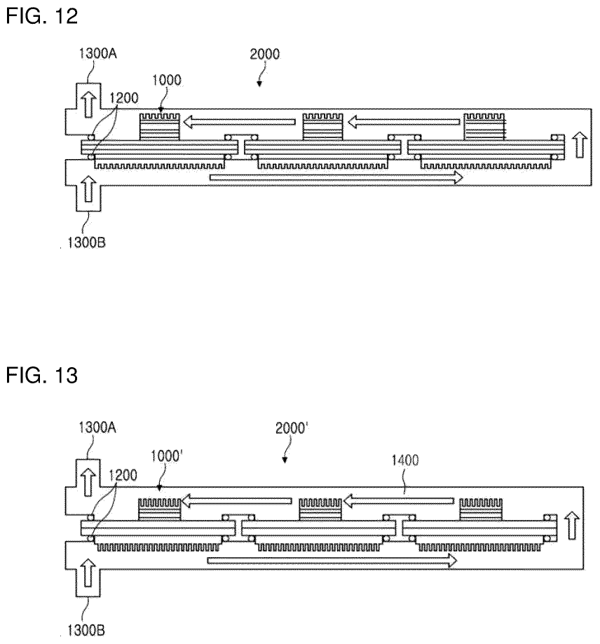

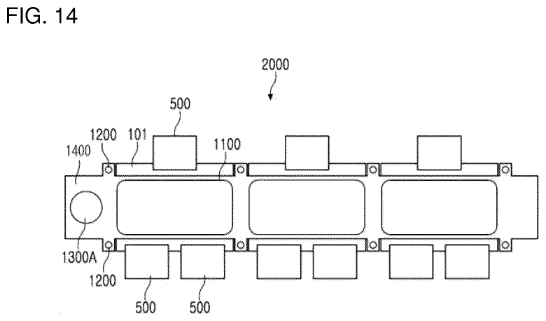

FIG. 12 is a side sectional view illustrating a cooler including a power module structure provided with a clip having a heat sink placed on an upper portion thereof according to an embodiment of the present disclosure. FIG. 13 is a side sectional view illustrating a cooler including a power module structure provided with a heat sink-integrated clip and a heat sink-integrated substrate according to an embodiment of the present disclosure. FIG. 14 is a plan view of a cooler provided with a power module structure according to an embodiment of the present disclosure.

Referring to FIGS. 12 to 14, cooling fluid may enter through an inlet 1300B placed on a lower surface of the cooler 2000 or 2000′, flow through the heat sink 400B or 440 on the lower surface, and move to an upper surface of the cooler 2000 or 2000′ via a right-side passage. The cooling fluid may then flow through the heat sink 400A or 380 on the upper surface and be discharged from an outlet 1300A placed on the upper surface. The plurality of protrusions 330, 430, 430′, and 430″ that are included in the heat sinks 400A and 400B, the heat sink-integrated substrate 450, and the heat sink-integrated clip 380 may be cooled by heat exchange with external cooling fluid, thus dissipating heat from opposite sides of the semiconductor chip 200. Particularly, since the power module structure 1000 or 1000′ does not employ two substrates, an insulating material is required to be used as the cooling fluid.

The housing 1400 may form the exterior of the cooler 2000 or 2000′, and may have various shapes to provide an internal space for cooling. The housing 1400 may include the inlet 1300B through which cooling fluid is drawn on one side, and the outlet 1300A through which air is discharged on the opposite side. The outlet 1300A may be placed on the upper surface of the cooler 2000 or 2000′, and the inlet 1300B on the lower surface, or vice versa. A flow path may be formed in the internal space of the housing 1400, thus allowing the cooling fluid drawn from the inlet 1300B to flow to the outlet 1300A. The flow path is illustrated with arrows in FIGS. 9 and 10.

The O-rings 1100 may prevent fluid leakage, and the power module structure 1000 or 1000′ may be fixed through eight cooler housing fastening portions 1200.

A method of manufacturing the cooler 2000 or 2000′ may include loading components of the cooler 2000 or 2000′ including the housing 1400, and fastening the O-rings 1100 to the upper and lower portions of the part that comes into surface contact with the housing 1400. Thereafter, the power module structure 1000 or 1000′ may be fastened, coupled to the housing 1400 using bolting as the fastening portions 1200, and packaged to complete the manufacturing process.

The packaging may include sealing through epoxy molding, and may prevent overheating of the power module, mitigate thermal shock, and protect the power module from external impacts, thereby improving mechanical strength and durability.

Hereinafter, the present disclosure will be described in more detail through embodiments and comparative examples. However, the embodiments are provided merely for illustrative purposes and should not be construed as limiting the scope of the present disclosure.

### EMBODIMENTS

### Embodiment 1

A solder preform made of Sn-0.7Cu was applied to a lower portion of a DBC substrate, and a first copper heat sink was placed. Thereafter, a solder preform of Sn-0.7Cu, an SiC chip, another solder preform of Sn-0.7Cu, a copper clip, another solder preform of Sn-0.7Cu, and a second copper heat sink were sequentially placed on an upper portion of the DBC substrate. Furthermore, a solder preform of Sn-0.7Cu was applied to a portion of the DBC substrate, and a distal end of the copper clip was placed thereon. A solder preform of Sn-0.7Cu was applied to another portion of the DBC substrate, and a terminal and an NTC thermistor were placed thereon.

Subsequently, the soldering equipment was used to heat the solder preforms at a temperature of 250° C. for 30 minutes to complete the soldering process, thereby fabricating the power module structure having the configuration shown in FIG. 8.

A plurality of rectangular prism-shaped pins were horizontally arranged with intervals therebetween on the first copper heat sink and the second copper heat sink to form protrusions.

### Embodiment 2

A solder preform of Sn-0.7Cu, an SiC chip, another solder preform of Sn-0.7Cu, and a heat sink-integrated clip were sequentially placed on an upper portion of a DBC substrate, which is a heat sink-integrated substrate. Furthermore, a solder preform of Sn-0.7Cu was applied to a portion of the DBC substrate, and a distal end of the copper clip was placed thereon. A solder preform of Sn-0.7Cu was applied to another portion of the DBC substrate, and a terminal and an NTC thermistor were placed thereon.

Subsequently, the soldering equipment was used to heat the solder preforms at a temperature of 250° C. for 30 minutes to complete the soldering process, thereby fabricating the power module structure having the configuration shown in FIG. 9.

The heat sink-integrated clip was formed by loading a copper clip and then horizontally arranging a plurality of rectangular prism-shaped pins with intervals therebetween on a surface facing away from a SiC chip contact surface of the portion to be formed as the SiC chip contact portion, thereby creating protrusions. Thereafter, a portion of the copper clip was bent to form a predetermined angle between the downset portion and the connection portion. The distal end of the copper clip was bent in a parallel shape to facilitate contact with the lead, thereby fabricating the clip with the structure illustrated in FIG. 1.

The heat sink-integrated substrate was loaded with a copper conductive layer, an AlN ceramic insulating layer, and a copper heat sink. A plurality of rectangular prism-shaped pins were horizontally arranged with intervals therebetween on the copper heat sink to form protrusions. Subsequently, the AlN ceramic insulating layer and the upper copper conductive layer, as well as the AlN ceramic insulating layer and the copper heat sink, were brazed using an AgCu bonding layer at a temperature of 750° C. to 950° C., thereby fabricating the substrate with the structure illustrated in FIG. 5.

### Comparative Example 1

Except for using general copper heat sinks without protrusions instead of the first copper heat sink and the second copper heat sink, the manufacturing process was carried out in the same manner as in Embodiment 1.

### Comparative Example 2

Except for not placing the second copper heat sink on the upper portion of the copper clip, sequentially placing a spacer, a DBC substrate, and a copper heat sink, and applying a silicone-based grease instead of a Sn-0.7Cu solder preform between the copper heat sink and the DBC substrate, the manufacturing process was carried out in the same manner as in Embodiment 1.

### Comparative Example 3

Except for not placing the heat sink-integrated clip on the upper portion of the SiC chip, the manufacturing process was carried out in the same manner as in Embodiment 2. The physical properties of the embodiments and comparative examples were evaluated using the following method, and the results are shown in Table 1.

### Physical Property Evaluation Method

### (1) Thermal Resistance (° C./W)

The thermal resistance of the power module structure was measured to evaluate the efficiency of heat transfer through the power module structure. Power was applied to the power module, and a temperature sensor was used to measure the temperature rise of the power module. The thermal resistance was calculated by dividing the temperature rise by the power consumption.

TABLE 1

| | Thermal resistance (° C./W) |
|---|---|
| Embodiment 1 | 0.1 |
| Embodiment 2 | 0.08 |
| Comparative Example 1 | 0.12 |
| Comparative Example 2 | 0.1 |
| Comparative Example 3 | 0.09 |

As shown in Table 1, Embodiment 1 according to the present disclosure exhibited a thermal resistance that was equal to or lower than that of Comparative Examples 1 and 2. Furthermore, Embodiment 2 exhibited a lower thermal resistance compared to Comparative Examples 1 to 3. The results demonstrate that the present disclosure can achieve excellent heat dissipation performance while simplifying the manufacturing process and reducing production costs.

The present disclosure may provide a power module structure that is characterized by excellent heat dissipation performance, a simplified manufacturing process, reduced manufacturing costs that results in superior economic efficiency, and a compact volume that leads to high efficiency, and a method of manufacturing the power module structure, and a cooler.

It will be understood by those skilled in the art that simple changes or modifications may be easily made, and such changes or modifications shall be considered to fall within the scope of the present disclosure.

What is claimed is:

1. A power module, comprising:
a first heat sink;
a substrate placed on an upper portion of the first heat sink;
a semiconductor chip placed on an upper portion of the substrate;
a clip placed on an upper portion of the semiconductor chip; and
a second heat sink placed on an upper portion of the clip,
wherein at least one of the first heat sink and the second heat sink is formed with one or more protrusions.

2. The power module of claim 1, wherein the semiconductor chip and the clip are bonded together.

3. The power module of claim 1, wherein the semiconductor chip and the clip are soldered together.

4. The power module of claim 1, wherein the substrate comprises a direct bonded copper (DBC) substrate.

5. The power module of claim 1, further comprising a terminal that is formed in one side of the substrate.

6. The power module of claim 1, further comprising a negative temperature coefficient (NTC) thermistor that is formed in one side of the substrate.

7. The power module of claim 1, further comprising a thermal interface material (TIM) that is formed between the substrate and the first heat sink.

8. A power module, comprising:
a heat sink-integrated substrate;
a semiconductor chip placed on an upper portion of the heat sink-integrated substrate; and
a heat sink-integrated clip placed on an upper portion of the semiconductor chip,
wherein the heat sink-integrated substrate and the heat sink-integrated clip are each formed with a plurality of protrusions.

9. The power module of claim 8,
wherein the heat sink-integrated clip comprises a clip configured to transmit current in a power module,
wherein the clip is made of a material that dissipates heat,
wherein one end of the clip has a stepped structure and configured to electrically connect to the substrate,
wherein the clip includes a first surface in contact with an upper portion of the semiconductor chip, and a second surface facing away from the first surface, and
wherein the second surface includes one or more protrusions.

10. The power module of claim 8, wherein the heat sink-integrated substrate comprises:
a ceramic insulating layer;
an upper conductive layer placed on an upper portion of the ceramic insulating layer; and
a heat sink placed on a lower portion of the ceramic insulating layer,
wherein the heat sink includes a first surface in contact with the ceramic insulating layer, and a second surface facing away from the first surface, and
wherein the second surface includes one or more protrusions.

11. The power module of claim 8, wherein the semiconductor chip and the heat sink-integrated clip are bonded together.

12. The power module structure of claim 8, wherein the semiconductor chip and the heat sink-integrated clip are soldered together.

13. The power module of claim 8, further comprising a terminal that is formed in one side of the heat sink-integrated substrate.

14. The power module of claim 8, further comprising a negative temperature coefficient (NTC) thermistor that is formed in one side of the heat sink-integrated substrate.

15. A method of manufacturing a power module, the method comprising:
placing a semiconductor chip on an upper portion of a heat sink-integrated substrate;
placing a heat sink-integrated clip on an upper portion of the semiconductor chip; and
bonding one side of the heat sink-integrated clip to a lead to establish electrical connection therebetween,
wherein the heat sink-integrated substrate and the heat sink-integrated clip each include one or more protrusions.

16. The method of claim 15, wherein heat is dissipated from opposite sides of the semiconductor chip to directly cool the semiconductor chip.
